(19) United States
(12) Patent Application Publication
(10) Pub. No.: US 2018/0374955 A1
(43) Pub. Date: Dec. 27, 2018

(54) SEMICONDUCTOR DEVICE, AND METHOD FOR MANUFACTURING SAME

(71) Applicant: Sharp Kabushiki Kaisha, Sakai City, Osaka (JP)

(72) Inventor: Tokuo YOSHIDA, Sakai City (JP)

(21) Appl. No.: 15/780,249

(22) PCT Filed: Nov. 28, 2016
(86) PCT No.: PCT/JP2016/085230

§ 371 Date: May 31, 2018

(30) Foreign Application Priority Data
Dec. 1, 2015 (JP) 2015-234558

(51) Int. Cl. H01L 29/786; H01L 27/146; H01L 27/12; H01L 31/032; G02F 1/1345; G02F 1/1368; G02F 1/1343; G02F 1/1333; G02F 1/1362

(52) U.S. Cl. CPC H01L 29/7869; H01L 29/78648; H01L 27/14609; H01L 27/1225; H01L 31/032; G02F 1/136227; G02F 1/1368; G02F 1/134336; G02F 1/133345; G02F 1/134363; G02F 1/13454

(57) ABSTRACT

A semiconductor device includes a circuit including a first TFT (101) which is an oxide semiconductor TFT, an inorganic insulating layer (11) covering the first TFT, a lower transparent electrode and an upper transparent electrode arranged with a dielectric layer (17) therebetween, and a shield layer (30) formed from the same transparent conductive film as the lower or upper transparent electrode, wherein: one of the lower and upper transparent electrodes is a common electrode; the shield layer (30) is electrically connected to the common electrode; the shield layer (30) includes a second gate electrode (BG) of the first TFT; and (a) the second gate electrode (BG) is arranged on the inorganic insulating layer so as to be in contact with an upper surface of the inorganic insulating layer, or (b) over a channel region of the first TFT, the dielectric layer (17) is in contact with the upper surface of the inorganic insulating layer (11), and the second gate electrode (BG) is arranged on the dielectric layer so as to be in contact with an upper surface of the dielectric layer.

### TECHNICAL FIELD

The present invention relates to a semiconductor device formed by using an oxide semiconductor, and a method for manufacturing the same.

### BACKGROUND ART

An active matrix substrate used in a liquid crystal display device, or the like, includes a switching element such as a thin film transistor (hereinafter, a “TFT”) for each pixel. TFTs using an amorphous silicon film as the active layer (hereinafter, “amorphous silicon TFTs”) and TFTs using a polycrystalline silicon film as the active layer (hereinafter, “polycrystalline silicon TFTs”) have conventionally been widely used as such switching elements.

In recent years, it has been proposed to use an oxide semiconductor as the material of the active layer of a TFT, instead of an amorphous silicon or a polycrystalline silicon. Such a TFT is referred to as an “oxide semiconductor TFT”. An oxide semiconductor has a higher mobility than an amorphous silicon. Therefore, an oxide semiconductor TFT is capable of operating faster than an amorphous silicon TFT.

On the other hand, techniques have been known in the art to monolithically (integrally) provide driver circuits such as a gate driver and a source driver on the substrate. These driver circuits (monolithic drivers) are normally formed by using TFTs. Recently, techniques have been used in the art to produce monolithic drivers on the substrate using oxide semiconductor TFTs, with which it is possible to narrow the bezel region or reduce the cost by simplifying the mounting process.

TFTs of the driver circuits (hereinafter, “circuit TFTs”) are typically produced simultaneously during the step of producing TFTs to be arranged as switching elements for respective pixels (hereinafter, “pixel TFTs”). Therefore, in many cases, circuit TFTs and pixel TFTs are formed by using the same oxide semiconductor film and have the same structure or similar structures. However, different characteristics are demanded for pixel TFTs and for circuit TFTs, and it is difficult to form oxide semiconductor TFTs that have both of the characteristics.

FIG. 20 is a graph illustrating the drain current (Id)-gate voltage (Vg) characteristics of an amorphous silicon TFT and an oxide semiconductor TFT. As can be seen from FIG. 20, with an oxide semiconductor TFT, which has a high mobility, the Id-Vg characteristic rises sharply. That is, the OFF leak current is small.

If TFTs having a small OFF leak current are used as pixel TFTs, the residual DC value may possibly fluctuate, causing charge non-uniformity. In order to prevent this, when oxide semiconductor TFTs are used as pixel TFTs, the OFF leak current is in some cases increased by lowering the threshold voltage of the oxide semiconductor TFTs.

However, using such oxide semiconductor TFTs as circuit TFTs may present a factor for an operation failure of peripheral circuits such as drivers. When used as circuit TFTs, there is required a structure that shifts the threshold voltage thereof in the positive direction with respect to the threshold voltage of pixel TFTs to further decrease the OFF leak current.

A TFT structure capable of changing the threshold voltage is described in Patent Document No. 1, for example. Patent Document No. 1 proposes providing a back gate electrode on an oxide semiconductor TFT so as to vary the threshold voltage based on the potential to be applied to the back gate electrode. A “back gate electrode” refers to an additional gate electrode that is arranged so as to oppose the gate electrode with a semiconductor layer sandwiched therebetween. In the present specification, a TFT including a back gate electrode may be referred to as a “backgate structure TFT”.

### CITATION LIST

### Patent Literature

Patent Document No. 1: Japanese Laid-Open Patent Publication No. 2015-92596

### SUMMARY OF INVENTION

### Technical Problem

However, when a back gate electrode is provided on a TFT, there is a need to form a contact portion for connecting the back gate electrode with another electrode or line, thereby increasing the area (device area) that is required for the formation of the TFT. Therefore, applying a backgate structure to a circuit TFT may possibly increase the circuit area, making it difficult to narrow the bezel region and reduce the size of the semiconductor device.

Embodiments of the present invention have been made in view of the above, and an object thereof is to provide a semiconductor device that includes a circuit having an oxide semiconductor TFT with a lowered OFF leak current and that can be made smaller.

### Solution to Problem

A semiconductor device according to an embodiment of the present invention is a semiconductor device having a display region including a plurality of pixels, the semiconductor device including: a substrate; a plurality of oxide semiconductor TFTs including a first TFT and a second TFT formed on the substrate, wherein the second TFT is arranged in each of the plurality of pixels; at least one circuit including the first TFT; an inorganic insulating layer covering the first TFT and the second TFT; a lower transparent electrode provided above the inorganic insulating layer in the display region; an upper transparent electrode arranged on the lower transparent electrode with a dielectric layer therebetween; and a shield layer formed from the same transparent conductive film as the lower transparent electrode or the upper transparent electrode, the shield layer covering the at least one circuit, wherein: each of the plurality of oxide semiconductor TFTs includes a first gate electrode, a gate insulating layer covering the first gate electrode, an oxide semiconductor layer arranged so as to oppose the first gate electrode with the gate insulating layer therebetween, and a source electrode and a drain electrode connected to the oxide semiconductor layer; one of the lower transparent electrode and the upper transparent electrode is a pixel electrode, the other one of the lower transparent electrode and the upper transparent electrode is a common electrode, and the drain electrode of the second TFT is electrically connected to the pixel electrode; the shield layer is electrically connected to the common electrode; the shield layer includes a second gate electrode arranged so as to overlap at least a part of a channel region of the oxide semiconductor layer of the first TFT, as seen from a direction normal to the substrate; and (a) the second gate electrode is arranged on the inorganic insulating layer so as to be in contact with an upper surface of the inorganic insulating layer, or (b) over the channel region of the first TFT, the dielectric layer is in contact with the upper surface of the inorganic insulating layer, and the second gate electrode is arranged on the dielectric layer so as to be in contact with an upper surface of the dielectric layer.

In one embodiment, the second gate electrode is not provided in the second TFT.

In one embodiment, the plurality of oxide semiconductor TFTs further include a third TFT; and the at least one circuit includes the third TFT, and the second gate electrode is not provided in the third TFT.

In one embodiment, the semiconductor device further includes an organic insulating layer arranged between the inorganic insulating layer and the lower transparent electrode and the shield layer, wherein: the organic insulating layer has an opening through which a part of the inorganic insulating layer is exposed, and the opening is arranged so as to overlap at least the channel region of the oxide semiconductor layer of the first TFT, as seen from a direction normal to the substrate; and the shield layer includes a shield portion that is located on the organic insulating layer, a connecting portion that is located on a side wall of the opening, and the second gate electrode that is located on a portion of the inorganic insulating layer exposed through the opening.

In one embodiment, the shield layer has an opening between the shield portion and the second gate electrode.

In one embodiment, the plurality of oxide semiconductor TFTs further include a third TFT; the at least one circuit includes the third TFT; and the oxide semiconductor layer of the third TFT is covered by the organic insulating layer, and the shield layer has an opening over the third TFT.

In one embodiment, a thickness of the organic insulating layer is 1 μm or more and 3 μm or less.

In one embodiment, the plurality of oxide semiconductor TFTs further include a third TFT; the at least one circuit includes the third TFT; an organic insulating layer is not provided between the inorganic insulating layer and the shield layer; and the shield layer has an opening over the third TFT.

In one embodiment, the at least one circuit is provided in a non-display region around the display region.

In one embodiment, the at least one circuit is provided in the display region; and the first TFT is located in one of the plurality of pixels, and the shield layer and the common electrode are formed integral together.

In one embodiment, a thickness of the inorganic insulating layer is 100 nm or more and 500 nm or less.

In one embodiment, the at least one circuit includes a gate driver.

In one embodiment, the plurality of oxide semiconductor TFTs are etch stop-type TFTs.

In one embodiment, the plurality of oxide semiconductor TFTs are channel-etch type TFTs.

In one embodiment, the oxide semiconductor layer includes an In—Ga—Zn—O-based semiconductor.

In one embodiment, the In—Ga—Zn—O-based semiconductor includes a crystalline portion.

In one embodiment, the oxide semiconductor layer has a layered structure.

A method for manufacturing a semiconductor device according to an embodiment of the present invention is a method for manufacturing a semiconductor device having a display region in which a plurality of pixels are arranged, the method including the steps of: (A) forming a plurality of oxide semiconductor TFTs including a first TFT and a second TFT, and at least one circuit including the first TFT, on a substrate, wherein the second TFT is arranged in each of the plurality of pixels; (B) forming an inorganic insulating layer so as to cover the first TFT and the second TFT; (C) forming a first transparent conductive film above the inorganic insulating layer and patterning the first transparent conductive film so as to form a lower transparent electrode; (D) forming a dielectric layer on the lower transparent electrode; (E) forming a second transparent conductive film on the dielectric layer and patterning the second transparent conductive film so as to form an upper transparent electrode; and (F) patterning the first transparent conductive film or the second transparent conductive film so as to form a shield layer covering the at least one circuit, wherein: each of the plurality of oxide semiconductor TFTs includes a first gate electrode, a gate insulating layer covering the first gate electrode, an oxide semiconductor layer arranged so as to oppose the first gate electrode with the gate insulating layer therebetween, and a source electrode and a drain electrode connected to the oxide semiconductor layer; one of the lower transparent electrode and the upper transparent electrode is a pixel electrode, and the other one of the lower transparent electrode and the upper transparent electrode is a common electrode; the shield layer is electrically connected to the common electrode; the shield layer includes a second gate electrode arranged so as to overlap at least a part of a channel region of the oxide semiconductor layer of the first TFT, as seen from a direction normal to the substrate; and (a) the second gate electrode is arranged on the inorganic insulating layer so as to be in contact with an upper surface of the inorganic insulating layer, or (b) over the channel region of the first TFT, the dielectric layer is in contact with the upper surface of the inorganic insulating layer, and the second gate electrode is arranged on the dielectric layer so as to be in contact with an upper surface of the dielectric layer.

In one embodiment, the method further includes, between the step (B) and the step (C), the step of forming an organic insulating layer on the inorganic insulating layer, and forming an opening in the organic insulating layer through which a part of the inorganic insulating layer is exposed, wherein: the opening is arranged so as to overlap at least the channel region of the oxide semiconductor layer of the first TFT, as seen from a direction normal to the substrate; and the shield layer includes a shield portion that is located on the organic insulating layer, a connecting portion that is located on a side wall of the opening, and the second gate electrode that is located on a portion of the inorganic insulating layer exposed through the opening.

### Advantageous Effects of Invention

According to an embodiment of the present invention, it is possible to provide a semiconductor device that includes a circuit having an oxide semiconductor TFT with a lowered OFF leak current and that can be made smaller.

### BRIEF DESCRIPTION OF DRAWINGS

FIG. 1 A schematic plan view illustrating a semiconductor device 1001 according to a first embodiment.

FIGS. 2 (a) and (b) are a cross-sectional view and a plan view, respectively, showing an example of a first TFT 101 in the semiconductor device 1001, and (c) shows a part of the circuit.

FIG. 3 A graph illustrating the backgate potential dependency of the Id-Vg characteristic of a backgate structure TFT.

FIGS. 4 (a) and (b) are plan views each showing another example of the first TFT 101.

FIG. 5 (a) is a plan view illustrating a pixel region of a semiconductor device 1002, and (b) is a cross-sectional view showing an example of a second TFT 201.

FIG. 6 A schematic cross-sectional view showing the first TFT 101 and the second TFT 201 of another semiconductor device 1002 according to the first embodiment.

FIG. 7 A schematic cross-sectional view showing the first TFT 101 and the second TFT 201 of still another semiconductor device 1003 according to the first embodiment.

FIG. 8 A schematic cross-sectional view showing the first TFT 101 and the second TFT 201 of still another semiconductor device 1004 according to the first embodiment.

FIG. 9 A schematic cross-sectional view showing the first TFT 101 and a third TFT 301 of still another semiconductor device 1005 according to the first embodiment.

FIGS. 10 (a) and (b) are process step cross-sectional views illustrating a method for manufacturing the semiconductor device 1002.

FIGS. 11 (a) and (b) are process step cross-sectional views illustrating the method for manufacturing the semiconductor device 1002.

FIG. 12 A cross-sectional view illustrating the first TFT 101, the second TFT 201 and the third TFT 301 of a semiconductor device 1006 according to a second embodiment.

FIG. 13 A schematic cross-sectional view showing the first TFT 101, the second TFT 201 and the third TFT 301 of another semiconductor device 1007 according to the second embodiment.

FIGS. 14 (a) and (b) are schematic plan views illustrating a semiconductor device 1008 according to a third embodiment.

FIG. 15 A diagram showing an example of an equivalent circuit of a gate driver 50 of the semiconductor device 1008.

FIG. 16 (a) is a plan view illustrating a pixel region of a part of the semiconductor device 1008, and (b) is a plan view showing an example of a transparent conductive layer 150 (including a common electrode CE and a shield layer 30) provided in the pixel region shown in (a).

FIG. 17 A plan view illustrating the third TFT 301.

FIGS. 18 (a) and (b) are a plan view and a cross-sectional view, respectively, showing a TFT 2001 having a backgate contact portion 210 according to Reference Example 1.

FIG. 19 A plan view illustrating a conventional shield layer.

FIG. 20 A graph showing drain current (Id)-gate voltage (Vg) characteristics of an amorphous silicon TFT and an oxide semiconductor TFT.

### DESCRIPTION OF EMBODIMENTS

### First Embodiment

A semiconductor device according to a first embodiment of the present invention will now be described with reference to the drawings. The semiconductor device of the present embodiment widely includes active matrix substrates, various display devices, electronic devices, etc. Herein, an active matrix substrate will be described as an example.

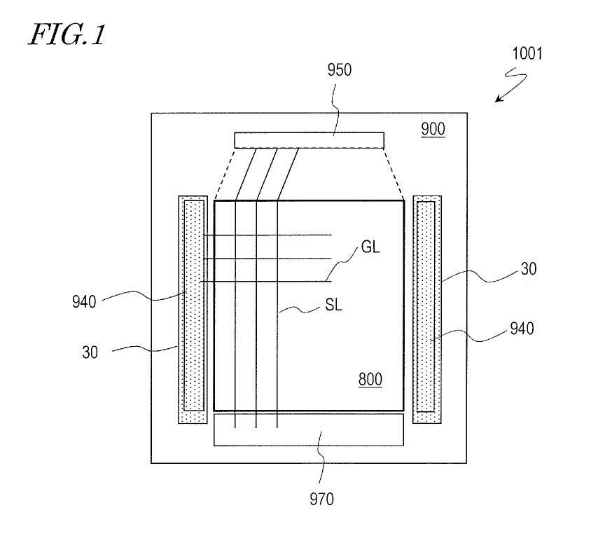

FIG. 1 is a schematic plan view illustrating a semiconductor device (active matrix substrate) 1001 of the present embodiment.

The semiconductor device 1001 has a display region 800 including a plurality of pixel regions, and a region (non-display region) 900 other than the display region 800. A “pixel region” is a region corresponding to a pixel of a display device, and may be referred to simply as a “pixel” in the present specification.

A plurality of gate lines GL and a plurality of source lines SL are formed in the display region 800, and each region defined by these lines serves as a “pixel”. A plurality of pixels are arranged in a matrix pattern. In each pixel, a TFT (pixel TFT) (not shown) is formed in the vicinity of the intersection between a source line SL and a gate line GL. In the present embodiment, an oxide semiconductor TFT of the bottom gate structure, which has no back gate electrode, for example, is used as the pixel TFT. A pixel electrode (not shown) is formed in each pixel. The drain electrode of each pixel TFT is electrically connected to the pixel electrode.

A common electrode (not shown) to which a common signal is applied is provided in the display region 800. The common electrode is connected to a common line (not shown). The pixel electrode and the common electrode are arranged so as to partially overlap each other with a dielectric layer therebetween. The pixel electrode may be arranged on the common electrode with the dielectric layer therebetween, or the common electrode may be arranged on the pixel electrode with the dielectric layer therebetween. In the present specification, one of the pixel electrode and the common electrode that is located on the substrate side may be referred to as a “lower transparent electrode”, and the other electrode as an “upper transparent electrode”.

Provided in a non-display region 900 are circuits such as a gate driver circuit 940, a test circuit 970 and a source switching circuit 950, a terminal section for electrically connecting the gate line GL or the source line SL with an external line, etc. TFTs (circuit TFTs) are formed in the non-display region 900 each as a circuit element of any of the circuits described above. At least one of the circuit TFTs is a backgate structure TFT.

As a countermeasure against display non-uniformity, a shield layer 30 is provided so as to cover some or all of the circuits (particularly, the gate driver circuit 940). The shield layer 30 is formed from the same transparent conductive film as the pixel electrode or the common electrode, for example. As will be described below, in the present embodiment, a part of the shield layer 30 is made to function as a back gate electrode of the circuit TFT.

At least one of the circuit TFTs of the present embodiment is an oxide semiconductor TFT (hereinafter, a “first TFT”) having a back gate electrode. The pixel TFT is an oxide semiconductor TFT (hereinafter, a “second TFT”) formed on the same substrate as the first TFT. The first and second TFTs may be formed by using the same oxide semiconductor film. Note that the semiconductor device 1001 may further include oxide semiconductor TFTs other than the first and second TFTs.

<First TFT>

First, the structure of the first TFT, which is the circuit TFT, will be described with reference to the drawings.

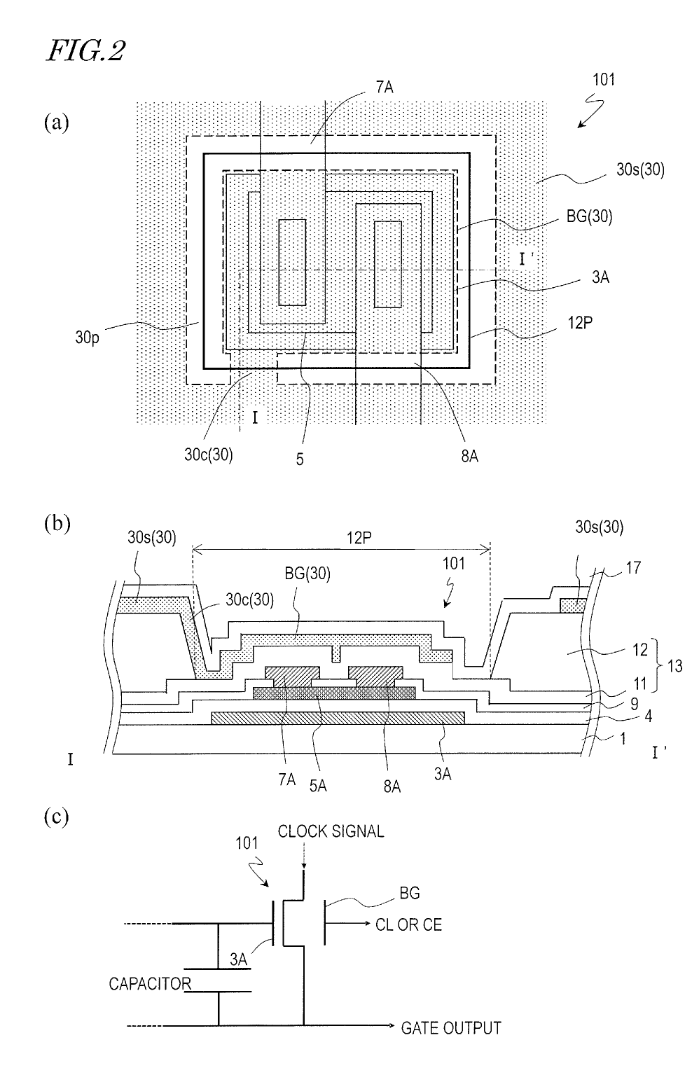

FIGS. 2(a) and 2(b) are a cross-sectional view and a plan view, respectively, showing an example of an oxide semiconductor TFT (hereinafter referred to as a “first TFT”.) 101 having a backgate structure in the semiconductor device 1001.

The first TFT 101 includes a substrate 1, a gate electrode 3A supported on the substrate 1, a gate insulating layer 4 covering the gate electrode (referred to also as a “first gate electrode”.) 3A, an oxide semiconductor layer 5A formed on the gate insulating layer 4 and serving as the active layer, a source electrode 7A and a drain electrode 8A, and a back gate electrode (referred to also as a “second gate electrode”.) BG. Hereinafter, the gate electrode 3A will be referred to as a “front gate electrode” to distinguish it from the back gate electrode BG. The oxide semiconductor layer 5A is arranged so as to oppose the front gate electrode 3A with the gate insulating layer 4 therebetween.

The source electrode 7A and the drain electrode 8A are each electrically connected to the oxide semiconductor layer 5A. A region of the oxide semiconductor layer 5A that is in contact with the source electrode 7A is referred to as a source contact region and a region thereof that is in contact with the drain electrode 8A as a drain contact region. A region of the oxide semiconductor layer 5A that is located between the source contact region and the drain contact region and overlaps the front gate electrode 3A with the gate insulating layer 4 therebetween serves as a channel region.

A protection layer 9 (an etch stop structure) to be in contact with the channel region may be provided between the oxide semiconductor layer 5A and the source electrode 7A and the drain electrode 8A. Herein, the protection layer 9 has openings, and the source contact region and the drain contact region of the oxide semiconductor layer 5A are exposed through the respective openings. The source electrode 7A and the drain electrode 8A are in contact with the oxide semiconductor layer 5A in the respective openings of the protection layer 9.

The first TFT 101 is covered by an interlayer insulating layer 13. The interlayer insulating layer 13 includes an inorganic insulating layer (passivation layer) 11, and an organic insulating layer 12 formed on the inorganic insulating layer 11. The organic insulating layer 12 may be a flattening film. The inorganic insulating layer 11 is an inorganic insulating film, which is typically made of SiNx, SiOx, or the like, and which has a thickness of 100 nm or more and 500 nm or less, for example. The organic insulating layer 12 is thicker than the inorganic insulating layer 11, and the thickness thereof is 1 μm or more and 3 μm or less, for example. The organic insulating layer 12 is used for purposes such as flattening the surface of the upper layer of the pixel TFT, and reducing the capacitance formed between the pixel electrode and the source line, etc.

The organic insulating layer 12 has an opening 12P, above the first TFT 101, through which the inorganic insulating layer 11 is exposed. The opening 12P is arranged so as to overlap at least the entire channel region as seen from the direction normal to the substrate 1. The opening 12P may be arranged so as to overlap the entire oxide semiconductor layer 5A.

The shield layer 30 is arranged on the interlayer insulating layer 13 and in the opening 12P. In the example shown in FIG. 2, the shield layer 30 is formed by using the same transparent conductive film as the lower transparent electrode (the common electrode or the pixel electrode). A portion of the shield layer 30 that is arranged so as to be in contact with the upper surface of the inorganic insulating layer 11 in the opening 12P functions as the back gate electrode BG of the first TFT 101. In such a case, the inorganic insulating layer 11 and the protection layer 9 serve as the gate insulating layer of the back gate electrode BG. The back gate electrode BG may be arranged so as to overlap at least the channel region, and may be arranged so as to overlap the entire oxide semiconductor layer 5A, as seen from the direction normal to the substrate 1.

The shield layer 30 (including the back gate electrode BG) is electrically connected to the common electrode, and has a common potential. FIG. 2(c) illustrates a part of a circuit including the first TFT 101. As shown in this example, the back gate electrode BG is connected to a common electrode CE or a common line CL.

Note that Japanese Laid-Open Patent Publication No. 2014-103142, for example, proposes a structure in which a back gate electrode is provided on an organic insulating layer. However, if a back gate electrode is provided on an organic insulating layer, the effect of preventing the fluctuation of the threshold voltage is reduced due to the presence of a relatively thick organic insulating layer between the semiconductor layer and the back gate electrode. In contrast, in the present embodiment, with the provision of the opening 12P in the organic insulating layer 12, there is no organic insulating layer between the back gate electrode BG and the oxide semiconductor layer 5A. Because only a relatively thin inorganic insulating film (the inorganic insulating layer 11 and the protection layer 9 in the etch stop structure, and the inorganic insulating layer 11 in the channel-etch structure) is arranged between the back gate electrode BG and the oxide semiconductor layer 5A, it is possible to more suitably perform a threshold control of the first TFT 101 by means of the back gate electrode BG.

In the example shown in FIG. 2, the shield layer 30 is formed in contact with the upper surface of the organic insulating layer 12, a part of the side surface of the opening 12P, and the upper surface of the inorganic insulating layer 11 exposed through the opening 12P. A portion of the shield layer 30 that is located on the organic insulating layer 12 may be referred to as a shield portion 30s, a portion thereof that is located above the first TFT 101 in the opening 12P as the back gate electrode BG, and a portion thereof that is located between the shield portion 30s and the back gate electrode BG as a connecting portion 30c. The shield portion 30s has the function of reducing display non-uniformity. The connecting portion 30c includes a portion that is located on the side wall of the opening 12P. It is only required that the connecting portion 30c be provided so that the shield portion 30s and the back gate electrode BG are generally at the same potential, and there is no particular limitation on the width, shape, etc., of the connecting portion 30c. The shield layer 30 may include an opening 30p between the shield portion 30s and the back gate electrode BG. The provision of the opening 30p reduces the capacitance formed between the source line and the shield layer 30 and the capacitance between the gate line and the shield layer 30.

When the shield layer 30 is formed from the same transparent conductive film as the common electrode, the shield layer 30 and the common electrode may be formed integral together. Alternatively, the shield layer 30 and the common electrode may be separated from each other, and may be electrically connected to each other via another conductive film (e.g., the same transparent conductive film as the pixel electrode). On the other hand, when the shield layer 30 is formed from the same transparent conductive film as the pixel electrode, the shield layer 30 may be connected directly to the common electrode or the common line in the contact hole provided in a dielectric layer 17. Alternatively, the shield layer 30 may be electrically connected to the common electrode or the common line via another conductive film.

According to the present embodiment, the OFF leak current of the first TFT 101 can be reduced to be lower than a TFT with no backgate. The reason for this will be described with reference to the drawings.

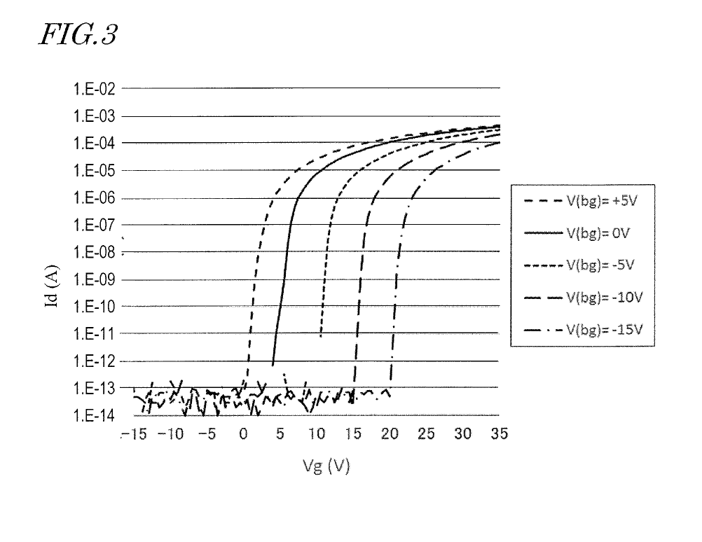

FIG. 3 is a graph illustrating the backgate potential dependency of the Id-Vg characteristic of a backgate structure TFT. It can be seen from FIG. 3 that the threshold voltage shifts positively when the backgate potential V (bg) is negative.

The back gate electrode BG of the present embodiment is a part of the shield layer 30 and has a common potential. The common potential is −1V to −2V, for example. As can be seen from FIG. 3, if a negative potential is given to the back gate electrode BG, the threshold voltage of the first TFT 101 shifts toward the positive direction. When the threshold voltage shifts positively, the OFF leak current decreases, and it is therefore possible to prevent a circuit operation failure due to the OFF leak current.

Normally, with a semiconductor device having a backgate TFT, a backgate contact portion for electrically connecting the back gate electrode with another conductive layer (e.g., a gate electrode, a line, and a source line, etc.) is additionally provided. Therefore, as compared with a TFT having no back gate electrode, the area (device area) required for the formation of the TFT increases.

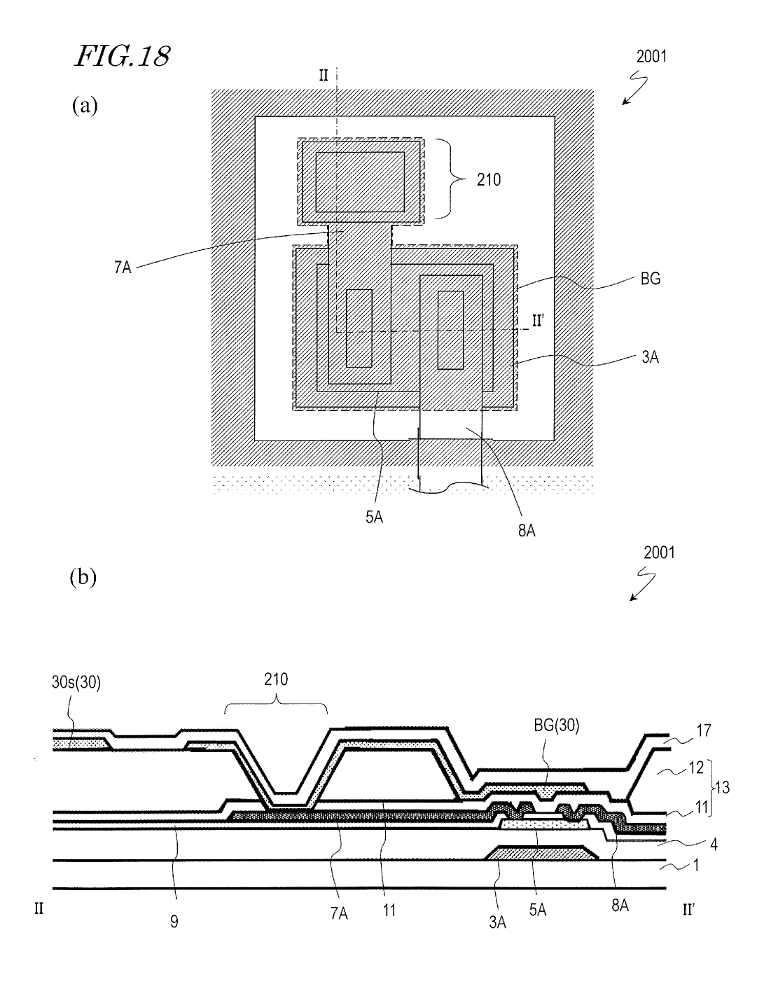

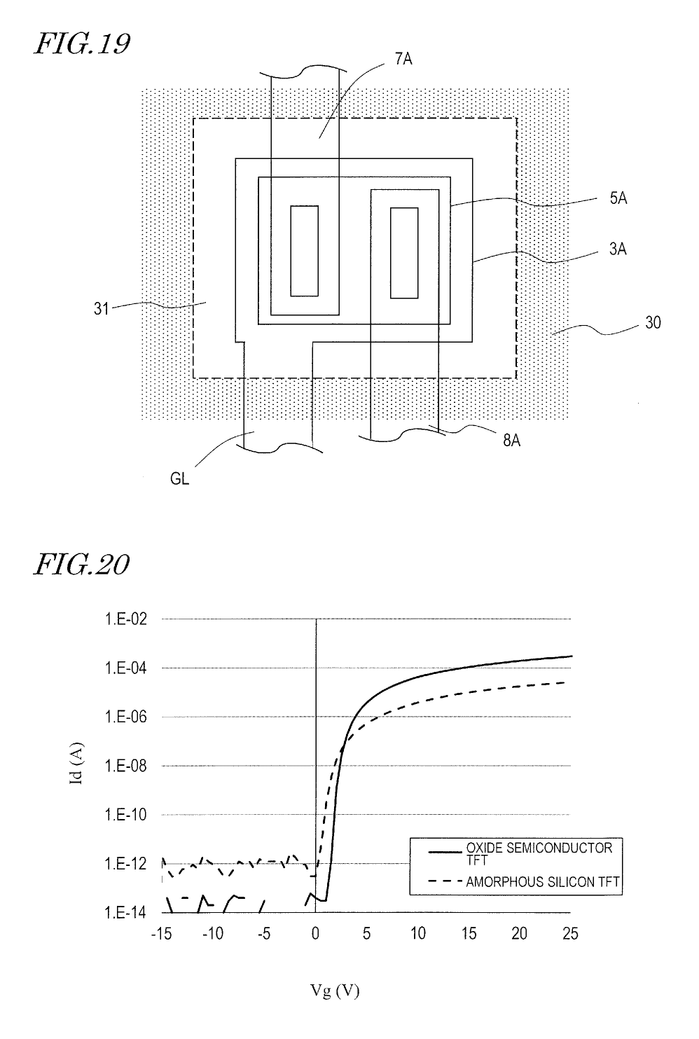

FIGS. 18(a) and 18(b) are a plan view and a cross-sectional view, respectively, showing a TFT 2001 having a backgate contact portion according to Reference Example 1. FIG. 18(b) shows a cross section taken along line II-II′ of FIG. 18(a). In FIG. 18, like elements to those of FIG. 2 are denoted by like reference signs.

The TFT 2001 of Reference Example 1 includes a backgate contact portion 210 that electrically connects together the back gate electrode BG and the source electrode 7A. In the backgate contact portion 210, the back gate electrode BG is connected to the source electrode 7A (or the source line) in the contact hole formed in the interlayer insulating layer. When the backgate contact portion 210 having a contact hole is provided as described above, the device area will increase significantly.

In contrast, according to the present embodiment, since a part of the shield layer 30 is used as the back gate electrode BG, there is no need, because of the addition of the back gate electrode BG, to additionally provide a contact portion for giving a potential to the back gate electrode BG. Therefore, the back gate electrode BG can be provided for some or all of the circuit TFTs without increasing the circuit area. Thus, it is possible to reduce the area of the non-display region (narrow the bezel region).

Note that the configuration in which a shield layer is provided on the gate driver circuit is described for example in Japanese Laid-Open Patent Publication No. 2008-203761, etc. The disclosure of Japanese Laid-Open Patent Publication No. 2008-203761 is herein incorporated by reference in its entirety. As can be seen also from this publication, a shield layer is conventionally provided on the circuit TFT with a relatively thick insulating film such as a flattening film therebetween in order to prevent the characteristic fluctuation of the circuit TFT due to the shield layer. When the circuit TFT is not covered by a flattening film, an opening 31 may conventionally be provided in the shield layer above the circuit TFT, as illustrated in FIG. 19.

In the present embodiment, as opposed to the conventional configuration, a part of the shield layer 30 is arranged on the upper surface of the inorganic insulating layer 11, which is used to adjust the threshold voltage of the circuit TFT. Therefore, it is possible to reduce the OFF leak current of the circuit TFT, thereby increasing the reliability of the circuit, without complicating the manufacturing process.

The shape of the back gate electrode BG of the first TFT 101 is not limited to the shape shown in FIG. 2(a). The back gate electrode BG may be formed integrally with the shield layer 30 and arranged so as to cover at least the channel region. It may have the same potential as the shield layer 30.

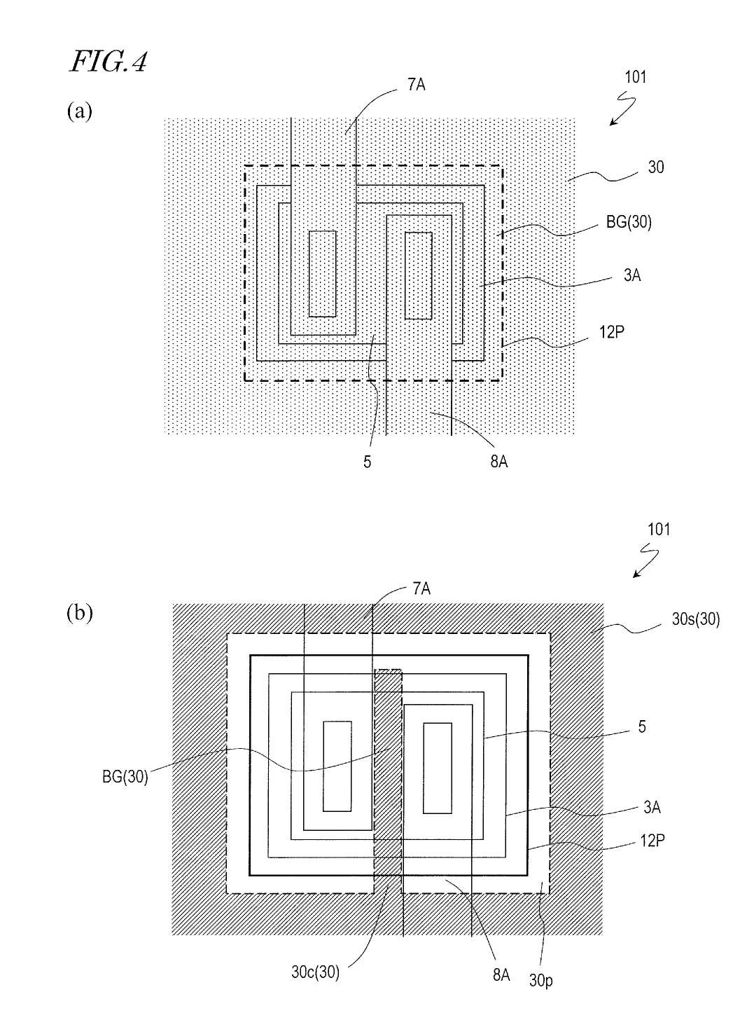

FIGS. 4(a) and 4(b) are plan views each showing another example of the first TFT 101. As shown in FIG. 4(a), the shield layer 30 may cover the entire first TFT 101 with no opening above the first TFT 101. A portion of the shield layer 30 that is located in the opening 12P of the organic insulating layer 12 functions as the back gate electrode BG. While the back gate electrode BG having generally the same size as the front gate electrode 3A is formed in the opening 30p of the shield layer 30 in FIG. 2(a), the size of the back gate electrode BG may be smaller than the size of the front gate electrode 3A. For example, as shown in FIG. 4(b), the back gate electrode BG may extend so as to cover the channel region from a part of the edge of the opening 30p of the shield layer 30. Such a configuration reduces the capacitance between the source line and the shield layer 30 and the capacitance between the gate electrode, the line and the shield layer 30.

<Second TFT and Pixel Region>

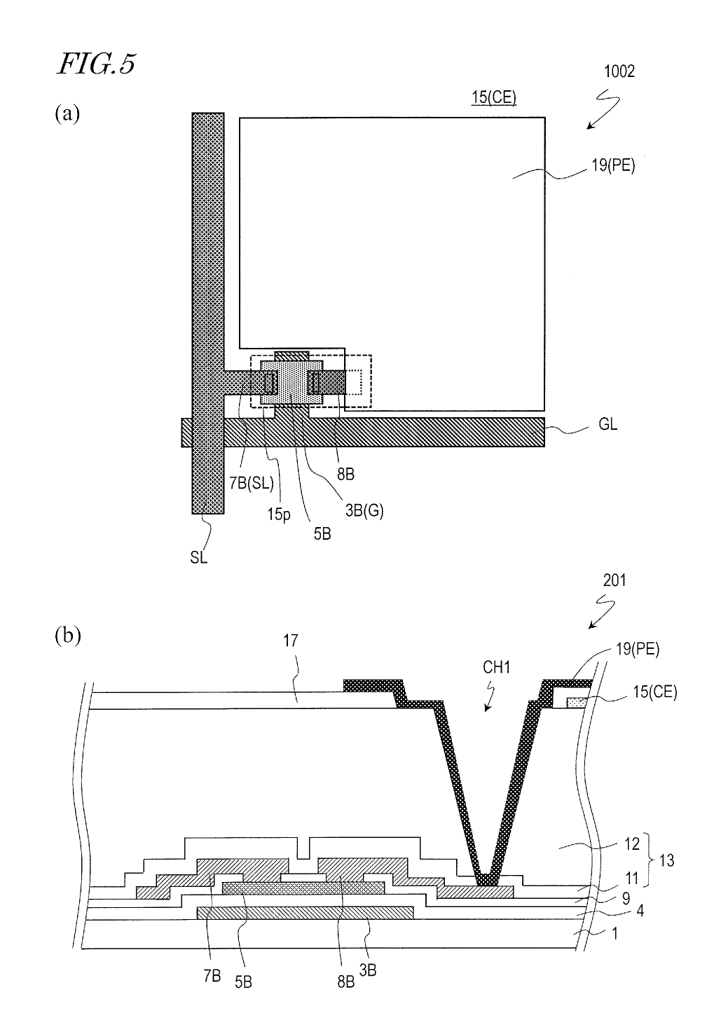

FIG. 5(a) is a plan view illustrating a pixel region of a semiconductor device 1002 of the present embodiment, and FIG. 5(b) is a cross-sectional view showing an example of the second TFT 201.

Each pixel region includes the second TFT 201, the gate line GL, the source line SL, the pixel electrode PE and the common electrode CE.

The second TFT 201 has a similar configuration to the first TFT 101, but does not include a back gate electrode. The second TFT 201 includes a gate electrode 3B supported on the substrate 1, the gate insulating layer 4 covering the gate electrode 3B, an oxide semiconductor layer 5B formed on the gate insulating layer 4 and serving as the active layer, and a source electrode 7B and a drain electrode 8B. The source electrode 7B and the drain electrode 8B are each electrically connected to the oxide semiconductor layer 5B. The gate electrode 3B is electrically connected to the gate line GL. The source electrode 7B is electrically connected to the source line SL. The protection layer 9 covering the channel region may be provided between the oxide semiconductor layer 5B and the source electrode 7B and the drain electrode 8B (an etch stop structure).

In the present embodiment, the gate electrodes 3A and 3B of the first TFT 101 and the second TFT 201 are formed from the same conductive film, the oxide semiconductor layers 5A and 5B are formed from the same oxide semiconductor film, and the source and drain electrodes 7A, 7B, 8A and 8B are formed from the same conductive film.

The interlayer insulating layer 13 including the inorganic insulating layer 11 and the organic insulating layer 12 is provided to extend over the second TFT 201. Formed above the interlayer insulating layer 13 are a lower transparent electrode 15, and an upper transparent electrode 19 that is arranged over the lower transparent electrode 15 with the dielectric layer 17 therebetween. Although not shown in the figure, the upper transparent electrode 19 has a slit or a notch for each pixel. In this example, the lower transparent electrode 15 is the common electrode CE, and the upper transparent electrode 19 is the pixel electrode PE. Such an electrode structure is described in International Publication WO2012/086513 pamphlet, for example. Note that the lower transparent electrode 15 may be the pixel electrode PE, and the upper transparent electrode 19 may be the common electrode CE. Such an electrode structure is described in Japanese Laid-Open Patent Publication No. 2008-032899 and Japanese Laid-Open Patent Publication No. 2010-008758, for example. The disclosures of International Publication WO2012/086513 pamphlet, Japanese Laid-Open Patent Publication No. 2008-032899 and Japanese Laid-Open Patent Publication No. 2010-008758 are herein incorporated by reference in their entirety.

The pixel electrode PE (here, the upper transparent electrode 19) is divided into pieces corresponding to pixels. The drain electrode 8B of the second TFT 201 is electrically connected to the corresponding pixel electrode PE. In this example, a contact hole (pixel contact hole) CH1 that reaches the drain electrode 8B is formed through the interlayer insulating layer 13 and the protection layer 9, and the upper transparent electrode 19 is provided on the interlayer insulating layer 13 and in the pixel contact hole CH1 so as to be in direct contact with the drain electrode 8B in the pixel contact hole CH1.

The common electrode CE (here, the lower transparent electrode 15) may not be divided into pieces corresponding to pixels. In this example, the common electrode CE has an opening 15p over the second TFT 201 of each pixel. The common electrode CE may be formed generally across the entire display region other than regions located over the second TFTs 201.

The first TFT 101 and the second TFT 201 of the present embodiment are etch stop-type TFTs, for example. With etch stop-type TFTs, a protection layer (etch stop layer) is formed on the channel region as shown in FIG. 2 and FIG. 5. The lower surfaces of the channel-side end portions of the source and drain electrodes are located on the etch stop layer, for example. An etch stop-type TFT is formed by, for example, forming an etch stop layer that covers a portion of the oxide semiconductor layer to be the channel region, then forming a source-drain electrode conductive film on the oxide semiconductor layer and the etch stop layer, and performing a source-drain separation.

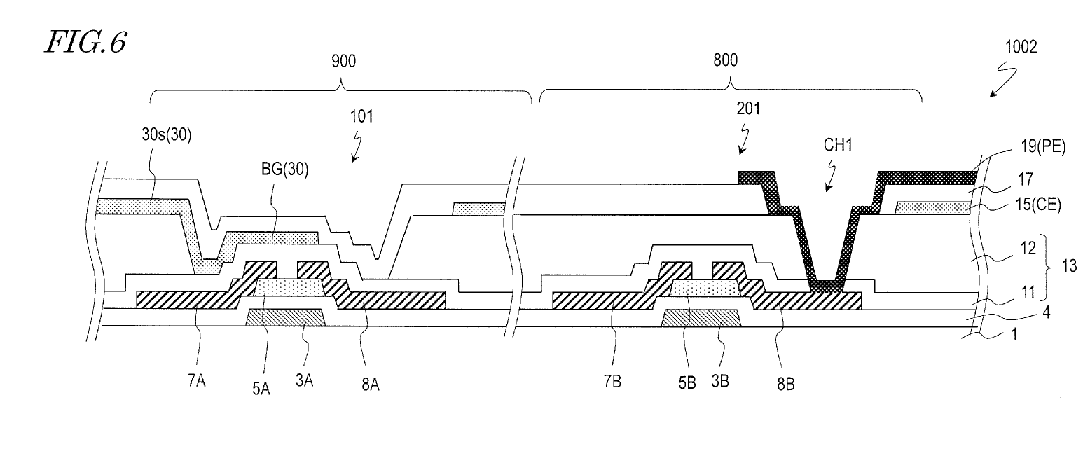

Note that the first TFT 101 and the second TFT 201 may be channel-etch type TFTs. FIG. 6 is a cross-sectional view illustrating the semiconductor device 1002 in which channel-etch type TFTs are used as the first and second TFTs 101 and 201. In a channel-etch type TFT, no etch stop layer is formed on the channel region, and the lower surfaces of the channel-side end portions of the source and drain electrodes are arranged so as to be in contact with the upper surface of the oxide semiconductor layer. A channel-etch type TFT is formed by, for example, forming a source-drain electrode conductive film on the oxide semiconductor layer, and performing a source-drain separation. In the source-drain separation step, a surface portion of the channel region may be etched.

<Variations>

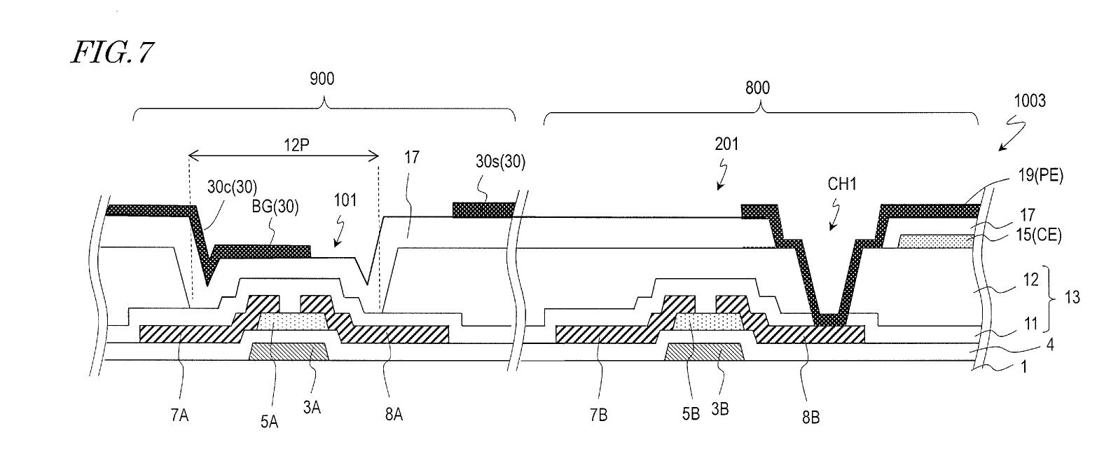

Another example of a semiconductor device of the present embodiment will now be described with reference to FIG. 7 to FIG. 9. In these figures, like elements to those of FIG. 2 and FIG. 5 are denoted by like reference signs and will not be described below.

While the shield layer 30 described above is formed from the same transparent conductive film as the lower transparent electrode 15 in the example shown in FIG. 2, the shield layer 30 may be formed from the same transparent conductive film as the upper transparent electrode 19 (here, the pixel electrode PE) as illustrated in FIG. 7. With a semiconductor device 1003 shown in FIG. 7, the organic insulating layer 12 has the opening 12P over the TFT 101. The dielectric layer 17 and the shield layer 30 are arranged on the organic insulating layer 12 and in the opening 12P. In the opening 12P, the dielectric layer 17 is in contact with the upper surface of the inorganic insulating layer 11, and the shield layer 30 is in contact with the upper surface of the dielectric layer 17. A portion of the shield layer 30 that is located in the opening 12P of the organic insulating layer 12 and overlaps the channel region with the inorganic insulating layer 11 and the dielectric layer 17 therebetween functions as the back gate electrode BG.

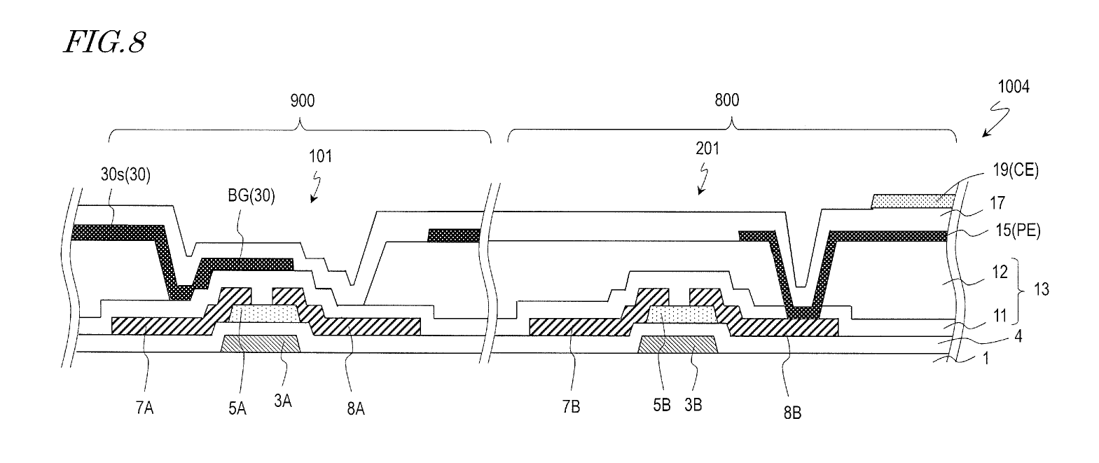

The lower transparent electrode 15 may be the pixel electrode PE, and the upper transparent electrode 19 may be the common electrode CE, as illustrated in FIG. 8.

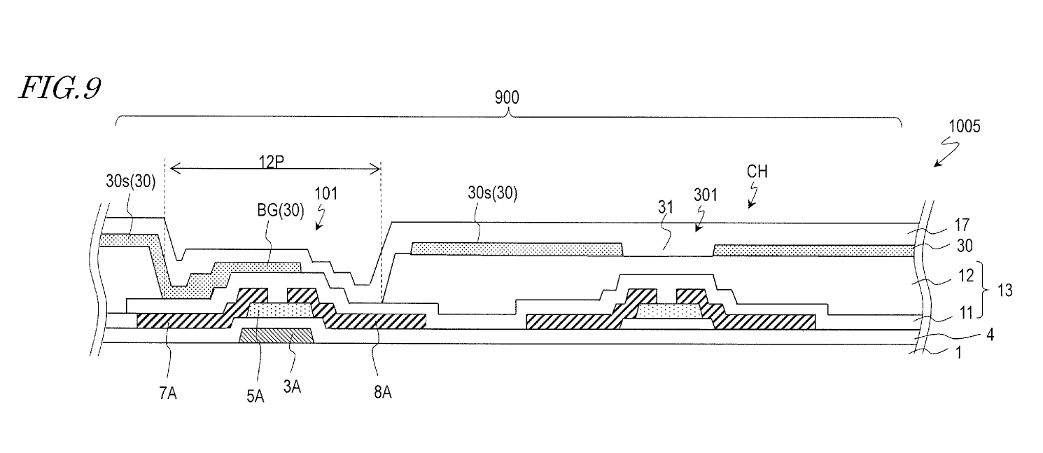

Moreover, the semiconductor device of the present embodiment may further include another circuit TFT that does not have the backgate structure. FIG. 9 is a cross-sectional view illustrating still another semiconductor device 1005 of the present embodiment. The semiconductor device 1005 includes the first TFT 101 and another circuit TFT (hereinafter, a “third TFT”) 301. These circuit TFTs may be formed in the same circuit. In this example, the organic insulating layer 12 covers the third TFT 301 but has the opening 12P over the first TFT 101. The shield layer 30 is provided on the organic insulating layer 12 and in the opening 12P. In the opening 12P, a portion located over the first TFT 101 functions as the back gate electrode BG. The shield layer 30 has the opening 31 over the third TFT 301. Thus, it is possible to more reliably prevent the characteristic fluctuation of the first TFT 301 due to the shield layer 30. Note that since the shield layer 30 is provided over the third TFT 301 with a relatively thick organic insulating layer 12 therebetween, the shield layer 30 does not need to have the opening 31 over the third TFT 301.

<Method for Manufacturing Semiconductor Device>

A method for manufacturing a semiconductor device of the present embodiment will be described with reference to the drawings, using a method for manufacturing the semiconductor device 1002 (FIG. 6) as an example.

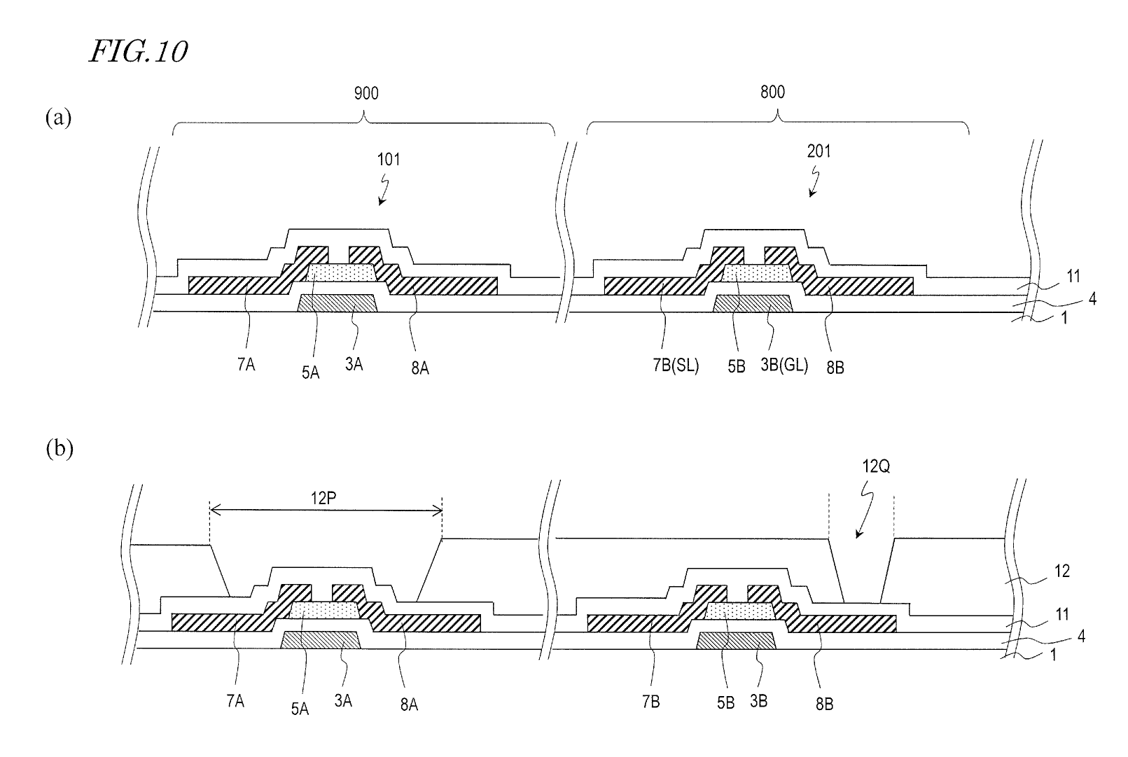

First, as shown in FIG. 10(a), circuits including the first TFT 101, the second TFT 201, the gate line GL, the source line SL, etc., are formed on the substrate 1 by a method known in the art.

Specifically, a gate line layer including the gate line GL and the gate electrodes 3A and 3B is formed on the substrate 1. The substrate may be, for example, a glass substrate, a silicon substrate, a heat-resistant plastic substrate (resin substrate), or the like. The gate line layer is obtained by forming a gate conductive film (thickness: 50 nm or more and 500 nm or less) on the substrate 1 by a sputtering method, or the like, and patterning the gate conductive film. The gate conductive film may suitably be a film including a metal such as aluminum (Al), tungsten (W), molybdenum (Mo), tantalum (Ta), chromium (Cr), titanium (Ti) or copper (Cu), an alloy thereof, or a metal nitride thereof. It may be a layered film including these films.

Then, the gate insulating layer (thickness: 200 nm or more and 500 nm or less) 4 is formed by a CVD method, or the like, so as to cover the gate line layer. The gate insulating layer 4 may suitably be a silicon oxide (SiOx) layer, a silicon nitride (SiNx) layer, a silicon oxide nitride (SiOxNy; x>y) layer, a silicon nitride oxide (SiNxOy; x>y) layer, or the like. The gate insulating layer 4 may have a layered structure.

Next, an oxide semiconductor film is formed on the gate insulating layer 4, and the oxide semiconductor film (thickness: 30 nm or more and 200 nm or less) is patterned so as to form the oxide semiconductor layer 5A to be the active layer of the circuit TFT, and the oxide semiconductor layer 5B to be the active layer of the pixel TFT. The oxide semiconductor film may have a layered structure.

When forming a TFT having an etch stop structure, a protection layer (thickness: 30 nm or more and 200 nm or less) to be the etch stop layer (channel protection layer) of the TFT is formed at this point. The protection layer may suitably be a silicon oxide (SiOx) layer, a silicon nitride (SiNx) layer, a silicon oxide nitride (SiOxNy; x>y) layer, a silicon nitride oxide (SiNxOy; x>y) layer, or the like. The protection layer may have a layered structure. Next, the protection layer is patterned so as to form a source opening through which the source contact region and the drain contact region of the oxide semiconductor layers 5A and 5B are exposed.

Thereafter, a source conductive film (thickness: 50 nm or more and 500 nm or less) is formed on the substrate 1 and is patterned so as to form the source line SL, and the source electrodes 7A and 7B and the drain electrodes 8A and 8B to be in contact with the oxide semiconductor layers 5A and 5B, thereby obtaining the first TFT 101 and the second TFT 201. The source conductive film may suitably be a film including a metal such as aluminum (Al), tungsten (W), molybdenum (Mo), tantalum (Ta), chromium (Cr), titanium (Ti) or copper (Cu), an alloy thereof, or a metal nitride thereof. It may be a layered film including these films.

Next, an inorganic insulating layer (thickness: 100 to 500 nm, preferably 200 to 500 nm, for example) 11 is formed by a CVD method, for example, so as to cover the first TFT 101 and the second TFT 201.

The inorganic insulating layer 11 may be an inorganic insulating film (passivation film) such as a silicon oxide (SiOx) film, a silicon nitride (SiNx) film, a silicon oxide nitride (SiOxNy; x>y) film or a silicon nitride oxide (SiNxOy; x>y) film. The inorganic insulating layer 11 may be a layered film.

Then, as shown in FIG. 10(b), an organic insulating layer (thickness: 1 to 3 μm, and preferably 2 to 3 μm, for example) 12 is formed on the inorganic insulating layer 11. An organic insulating film including a photosensitive resin material may be formed as the organic insulating layer 12. Next, the organic insulating layer 12 is patterned by a photolithography step so as to provide the openings 12P and 12Q in the organic insulating layer 12. The opening 12P is arranged so that a portion of the inorganic insulating layer that is located over the first TFT 101 is exposed therethrough, and the opening 12Q is arranged so that a portion of the inorganic insulating layer 11 that is located over the drain electrode 8B of the second TFT 201 is exposed therethrough.

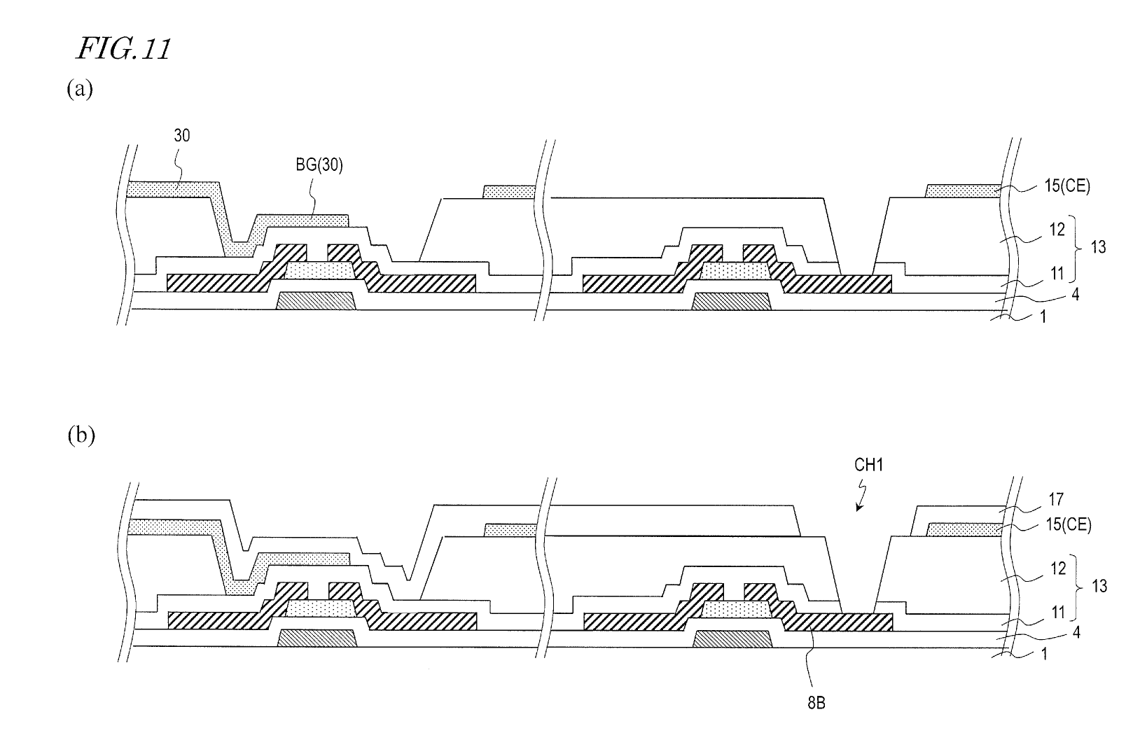

Then, as shown in FIG. 11(a), the lower transparent electrode 15 to be the common electrode CE, and the shield layer 30 are formed. The lower transparent electrode 15 and the shield layer 30 are obtained by forming a first transparent conductive film (thickness: 50 nm or more and 200 nm or less) on the organic insulating layer 12 and in the openings 12P and 12Q and patterning the first transparent conductive film. The first transparent conductive film may be, for example, an ITO (indium tin oxide) film, an In—Zn—O-based oxide (indium zinc oxide) film, a ZnO film (zinc oxide film), or the like.

Then, as shown in FIG. 11(b), the dielectric layer 17 is formed so as to cover the lower transparent electrode 15. The dielectric layer 17 may suitably be a silicon nitride (SiNx) film, a silicon oxide (SiOx) film, a silicon oxide nitride (SiOxNy; x>y) film, a silicon nitride oxide (SiNxOy; x>y) film, or the like. When a storage capacitor is formed by the lower transparent electrode 15, the dielectric layer 17 and the upper transparent electrode 19, the dielectric layer 17 may preferably be SiNx in view of the dielectric constant and the insulation. The thickness of the dielectric layer 17 is 70 nm or more and 300 nm or less, for example.

Thereafter, a resist layer (not shown) is formed, and the dielectric layer 17 and the inorganic insulating layer 11 are etched using the resist layer and the organic insulating layer 12 as an etching mask, thereby forming the pixel contact hole CH1.

Next, a second transparent conductive film is formed on the dielectric layer 17 and in the pixel contact hole CH1, and the second transparent conductive film is patterned, thereby obtaining the upper transparent electrode 19 to be the pixel electrode PE. A preferred material and a preferred thickness of the second transparent conductive film may be the same as those of the first transparent conductive film. The semiconductor device 1002 is manufactured as described above.

With the method as described above, it is possible to produce the TFTs 101 and 201 by using a conventional process for producing a display device TFT substrate, without newly adding a step of providing the back gate electrode BG.

<Regarding Oxide Semiconductor>

The oxide semiconductor included in the oxide semiconductor layers 5A and 5B may be an amorphous oxide semiconductor or a crystalline oxide semiconductor having a crystalline portion. Examples of the crystalline oxide semiconductor include a polycrystalline oxide semiconductor, a microcrystalline oxide semiconductor, and a crystalline oxide semiconductor whose c-axis is oriented generally perpendicular to the layer surface.

The oxide semiconductor layers 5A and 5B may have a layered structure including two or more layers. When the oxide semiconductor layers 5A and 5B have a layered structure, the oxide semiconductor layers 5A and 5B may include a non-crystalline oxide semiconductor layer and a crystalline oxide semiconductor layer. Alternatively, they may include a plurality of crystalline oxide semiconductor layers having different crystalline structures. They may include a plurality of non-crystalline oxide semiconductor layers. When the oxide semiconductor layers 5A and 5B have a two-layer structure including an upper layer and a lower layer, it is preferred that the energy gap of the oxide semiconductor included in the upper layer is greater than the energy gap of the oxide semiconductor included in the lower layer. Note however that when the energy gap difference between these layers is relatively small, the energy gap of the oxide semiconductor of the lower layer may be greater than the energy gap of the oxide semiconductor of the upper layer.

The material, the structure, the film formation method of the non-crystalline oxide semiconductor and each of the crystalline oxide semiconductors, and the configuration of an oxide semiconductor layer having a layered structure, etc., are described in Japanese Laid-Open Patent Publication No. 2014-007399, for example. The disclosure of Japanese Laid-Open Patent Publication No. 2014-007399 is herein incorporated by reference in its entirety.

The oxide semiconductor layers 5A and 5B may at least include one metal element from among In, Ga and Zn, for example. In the present embodiment, the oxide semiconductor layers 5A and 5B include an In—Ga—Zn—O-based semiconductor (e.g., indium gallium zinc oxide), for example. Now, the In—Ga—Zn—O-based semiconductor is a ternary oxide of In (indium), Ga (gallium) and Zn (zinc), and there is no particular limitation on the ratio (composition ratio) between In, Ga and Zn, examples of which include In:Ga:Zn=2:2:1, In:Ga:Zn=1:1:1 and In:Ga:Zn=1:1:2, for example. Such oxide semiconductor layers 5A and 5B can be formed from an oxide semiconductor film including an In—Ga—Zn—O-based semiconductor.

The in-Ga—Zn—O-based semiconductor may be amorphous or crystalline. The crystalline In—Ga—Zn—O-based semiconductor is preferably a crystalline In—Ga—Zn—O-based semiconductor whose c-axis is oriented generally perpendicular to the layer surface.

Note that crystalline structures of crystalline In—Ga—Zn—O-based semiconductors are disclosed in, for example, Japanese Laid-Open Patent Publication No. 2014-007399, supra, Japanese Laid-Open Patent Publication No. 2012-134475, Japanese Laid-Open Patent Publication No. 2014-209727, etc. The disclosures of Japanese Laid-Open Patent Publication No. 2012-134475 and Japanese Laid-Open Patent Publication No. 2014-209727 are herein incorporated by reference in their entirety. Since TFTs including an In—Ga—Zn—O-based semiconductor layer have a high mobility (more than 20 times that of an a-SiTFT) and a low leak current (less than 1/100 that of an a-SiTFT), they can desirably be used as driver TFTs (e.g., TFTs included in driver circuits provided around the display region including a plurality of pixels and on the same substrate as the display region) and pixel TFTs (TFTs provided in pixels).

The oxide semiconductor layers 5A and 5B may include another oxide semiconductor instead of an In—Ga—Zn—O-based semiconductor. For example, it may include an In—Sn—Zn—O-based semiconductor (e.g., In₂O₃—SnO₂—ZnO; InSnZnO). The In—Sn—Zn—O-based semiconductor is a ternary oxide of In (indium), Sn (tin) and Zn (zinc). Alternatively, the oxide semiconductor layers 5A and 5B may include an In—Al—Zn—O-based semiconductor, an In—Al—Sn—Zn—O-based semiconductor, a Zn—O-based semiconductor, an In—Zn—O-based semiconductor, a Zn—Ti—O-based semiconductor, a Cd—Ge—O-based semiconductor, a Cd—Pb—O-based semiconductor, a CdO (cadmium oxide), an Mg—Zn—O-based semiconductor, an In—Ga—Sn—O-based semiconductor, an In—Ga—O-based semiconductor, a Zr—In—Zn—O-based semiconductor, an Hf—In—Zn—O-based semiconductor, or the like.

### Second Embodiment

A semiconductor device according to a second embodiment is different from the semiconductor devices 1001 to 1005 of the first embodiment in that the interlayer insulating layer 13 does not include an organic insulating layer.

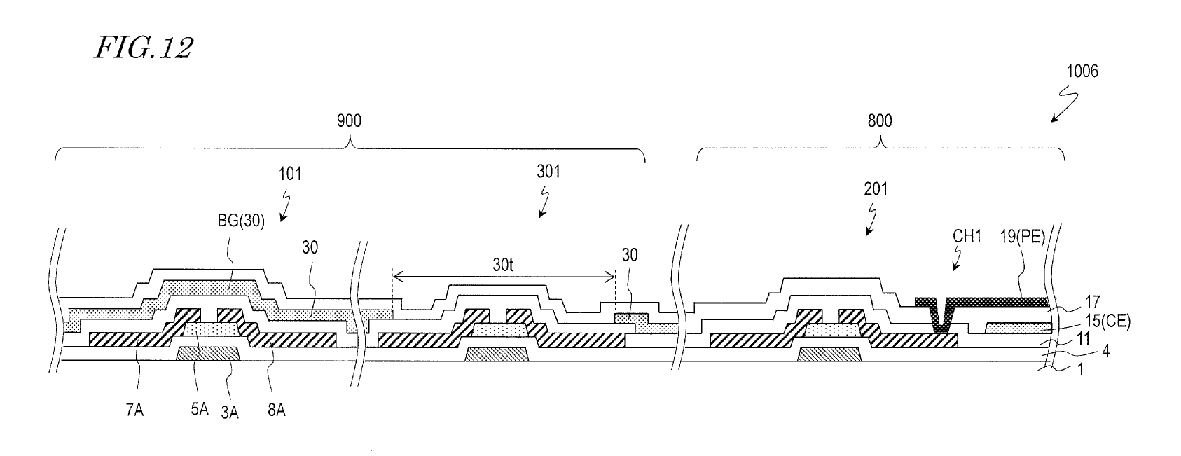

FIG. 12 is a cross-sectional view illustrating the first TFT 101 and the second TFT 201 of a semiconductor device 1006 of the present embodiment. Like elements to those of FIG. 2 and FIG. 5 are denoted by like reference signs. Differences from the above-described embodiment will now be described.

With the semiconductor device 1006, while the interlayer insulating layer 13 includes the inorganic insulating layer (passivation film) 11, it does not include a flattening film or an organic insulating film. The shield layer 30, the lower transparent electrode 15, the dielectric layer 17 and the upper transparent electrode 19 are provided on the inorganic insulating layer 11. The shield layer 30 is provided in contact with the upper surface of the inorganic insulating layer 11. In this example, the shield layer 30 is formed from the same transparent conductive film as the lower transparent electrode 15. A part of the shield layer 30 overlaps the channel region of the oxide semiconductor layer 5A with the inorganic insulating layer 11 therebetween, and functions as the back gate electrode BG.

The semiconductor device 1006 may further include another circuit TFT (third TFT) 301 that does not have the backgate structure. The shield layer 30 may have an opening 30t over the channel region of the third TFT 301. Then, it is possible to reduce the influence of the shield layer 30 on the characteristics of the third TFT 301, and it is therefore possible to positively shift the threshold voltage of only some of the circuit TFTs.

With a conventional semiconductor device, when the interlayer insulating layer 13 does not include a flattening film and only includes a passivation film, a shield layer arranged over a peripheral circuit such as a gate driver circuit is normally provided with openings located over circuit TFTs (see FIG. 19). This is to reduce the characteristic fluctuation of the circuit TFT due to the shield layer. In contrast, according to the present embodiment, the shield layer 30 does not have openings over channel regions of those of circuit TFTs that are to be TFTs of the backgate structure. Thus, the shield layer 30 can function as the back gate electrode BG for some or all of the circuit TFTs.

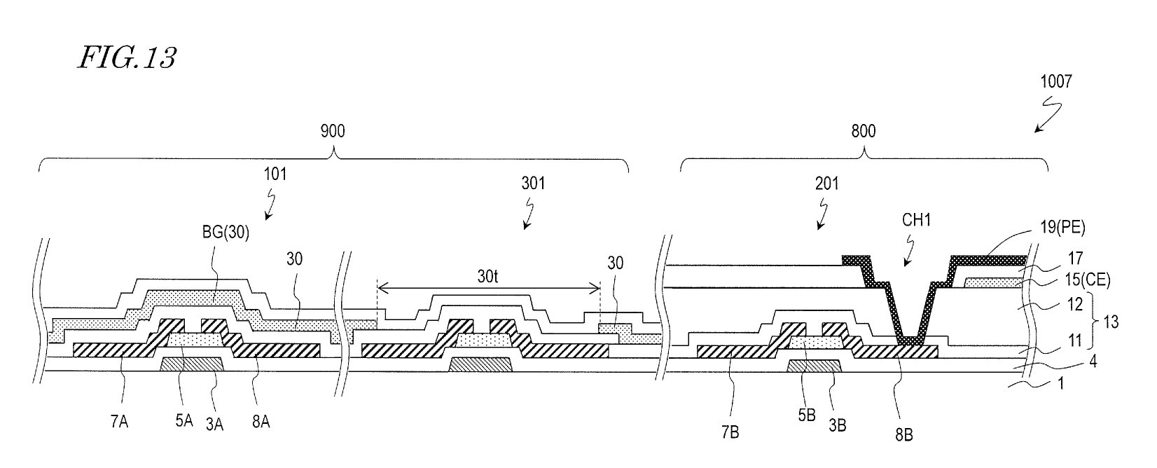

FIG. 13 is a cross-sectional view showing another semiconductor device 1007 of the present embodiment. As shown in FIG. 13, the organic insulating layer 12 may be formed in the display region and removed over circuits in the non-display region.

The structure of the semiconductor device of the present embodiment is not limited to the structure shown in FIG. 12 and FIG. 13. The first TFT 101 and the second TFT 201 may be of the etch stop-type. The lower transparent electrode 15 may be the pixel electrode PE, and the upper transparent electrode 19 may be the common electrode CE. Moreover, the shield layer 30 may be formed by using the same transparent conductive film as the upper transparent electrode 19.

### Third Embodiment

A semiconductor device according to a third embodiment is different from the above-described embodiment in that some or all of the circuit TFTs are formed in the pixel region.

Herein, the structure of the semiconductor device of the present embodiment will be described using an example in which gate driver circuits are distributed among a plurality of pixel regions. A configuration in which gate drivers are provided in pixels is disclosed for example in International Publication WO2014/069529 pamphlet by the same applicant. The disclosure of International Publication WO2014/069529 pamphlet is herein incorporated by reference in its entirety.

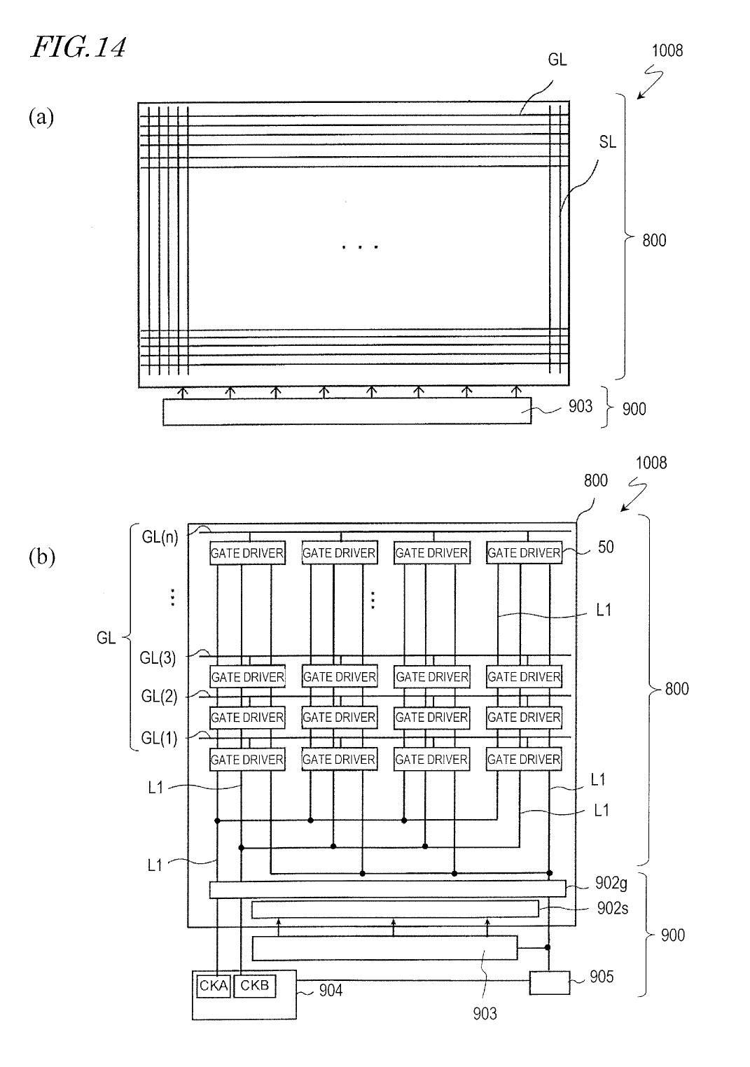

FIG. 14(a) is a plan view schematically showing a semiconductor device 1008 of the present embodiment. The semiconductor device 1008 includes a plurality of gate lines GL arranged in the row direction, and a plurality of source lines SL arranged in the column direction. The display region 800 includes a plurality of pixel regions. Each region surrounded by the gate lines GL and the source lines SL serves as a pixel region. Circuits such as the source driver are provided in the non-display region 900. Gate drivers 50 are arranged in the display region 800.

FIG. 14(b) is a schematic plan view showing the semiconductor device 1008, in which the source lines SL are omitted. As shown in the figure, the gate drivers 50 are provided between adjacent gate lines GL in the display region 800. The gate drivers 50 are distributed among a plurality of pixel regions. In this example, four gate drivers 50 are connected to each gate line GL. Lines L1 of the gate drivers 50 are connected to a terminal section 902g provided in the non-display region 900. The terminal section 902g is connected to a control circuit 904 and a power source 905. The terminal section 902g receives signals such as control signals (CKA, CKB) output from the control circuit 904 and the power source 905 and the power source voltage signal. Signals such as the control signals (CKA, CKB) and the power source voltage signal that have been input to the terminal section 902g are supplied to the gate drivers 50 via the lines L1. Each gate driver 50 outputs, to the gate line GL to which it is connected, a voltage signal that represents one of the selected state and the non-selected state based on the signal supplied thereto, and also outputs the voltage signal to the gate line GL of the next line. In the description below, voltage signals corresponding respectively to the selected state and the non-selected state may be referred to as scanning signals.

Also formed in the non-display region 900 are a source driver 903, and a terminal section 902s that connects together the source driver 903 and the source line SL. The source driver 903 outputs data signals to the source lines SL based on the control signal that is input thereto from the display control circuit 904.

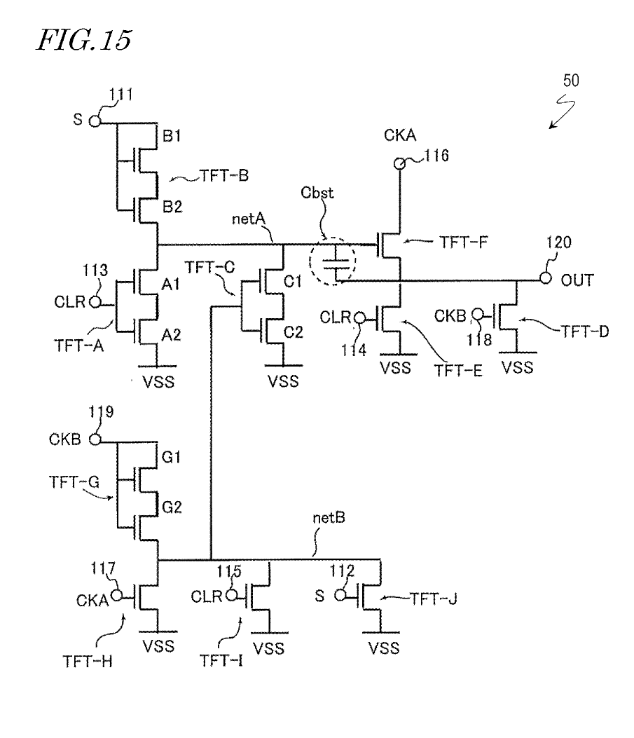

FIG. 15 is a diagram showing an example of an equivalent circuit of a gate driver 50 that is arranged between a gate line GL(n−1) and a gate line GL(n−2) for driving the gate line GL(n−1). The gate driver 50 includes TFT-A to TFT-J as circuit TFTs, a capacitor Cbst, terminals 111 to 120, and a group of terminals to which low-level power source voltage signals are input.

The terminals 111 and 112 receive the set signal (S) via the gate line GL of the preceding line GL(n−2). Note that the terminals 111 and 112 of the gate driver 50 connected to the gate line GL of the line GL(1) receive the gate start pulse signal (S) that is output from the display control circuit 904. The terminals 113 to 115 receive the reset signal (CLR) output from the display control circuit 904. The terminals 116 and 117 receive the clock signal (CKA) input thereto. The terminals 118 and 119 receive the clock signal (CKB) input thereto. The terminal 120 outputs the set signal (OUT) to the gate line GL of the following line.

The clock signal (CKA) and the clock signal (CKB) are two-phase clock signals whose phase is inverted every horizontal scanning period. FIG. 15 illustrates the gate driver 50 for driving the gate line GL of the line GL(n−1). However, for the gate driver 50 of the following line for driving the line GL(n), the terminals 116 and 117 receive the clock signal (CKB) and the terminals 118 and 119 receive the clock signal (CKA). That is, the terminals 116 and 117 and the terminals 118 and 119 of each gate driver 50 receive clock signals that are anti-phase with the clock signals that are received by the gate driver 50 of an adjacent row.

In FIG. 15, the designation netA refers to a line to which the source terminal of TFT-B, the drain terminal of TFT-A, the drain terminal of TFT-C, and one electrode of the capacitor Cbst and the gate terminal of TFT-F are connected. The designation netB refers to a line to which the gate terminal of TFT-C, the source terminal of TFT-G, the drain terminal of TFT-H, the drain terminal of TFT-I and the drain terminal of TFT-J are connected.

TFT-A includes two TFTs (A1, A2) connected together in series. The gate terminals of TFT-A are connected to the terminal 113, the drain terminal of A1 is connected to netA, and the source terminal of A2 is connected to the power source voltage terminal VSS.

TFT-B includes two TFTs (B1, B2) connected together in series. The gate terminals of TFT-B and the drain terminal of B1 are connected to the terminal 111 (diode connection), and the source terminal of B2 is connected to netA.

TFT-C includes two TFTs (C1, C2) connected together in series. The gate terminals of TFT-C are connected to netB, the drain terminal of C1 is connected to netA, and the source terminal of C2 is connected to the power source voltage terminal VSS.

One electrode of the capacitor Cbst is connected to netA and the other electrode thereof is connected to the terminal 120.

TFT-D has a gate terminal connected to the terminal 118, a drain terminal connected to the terminal 120 and a source terminal connected to the power source voltage terminal VSS. TFT-E has a gate terminal connected to the terminal 114, a drain terminal connected to the terminal 120, and a source terminal connected to the power source voltage terminal VSS. TFT-F has a gate terminal connected to netA, a drain terminal connected to the terminal 116, and a source terminal connected to the output terminal 120. TFT-G includes two TFTs (G1, G2) connected together in series. Each gate terminal of TFT-G and the drain terminal of G1 are connected to the terminal 119 (diode connection), and the source terminal of G2 is connected to netB. TFT-H has a gate terminal connected to the terminal 117, a drain terminal connected to netB, and a source terminal connected to the power source voltage terminal VSS. TFT-I has a gate terminal connected to the terminal 115, a drain terminal connected to netB, and a source terminal connected to the power source voltage terminal VSS. TFT-J has a gate terminal connected to the terminal 112, a drain terminal connected to netB, and a source terminal connected to the power source voltage terminal VSS.

Note that while FIG. 15 shows an example in which TFT-A, B, C and G each include two TFTs connected in series, these TFTs may each include one TFT.

Also in the present embodiment, as in the above-described embodiment, a shield layer (common electrode) is provided on the gate drivers 50, and the shield layer is used to form back gate electrodes for some or all of the circuit TFTs.

Hereinafter, a more specified configuration of the semiconductor device 1008 will be described with respect to an example of an active matrix substrate used in a display device of an FFS (Fringe Field Switching) mode.

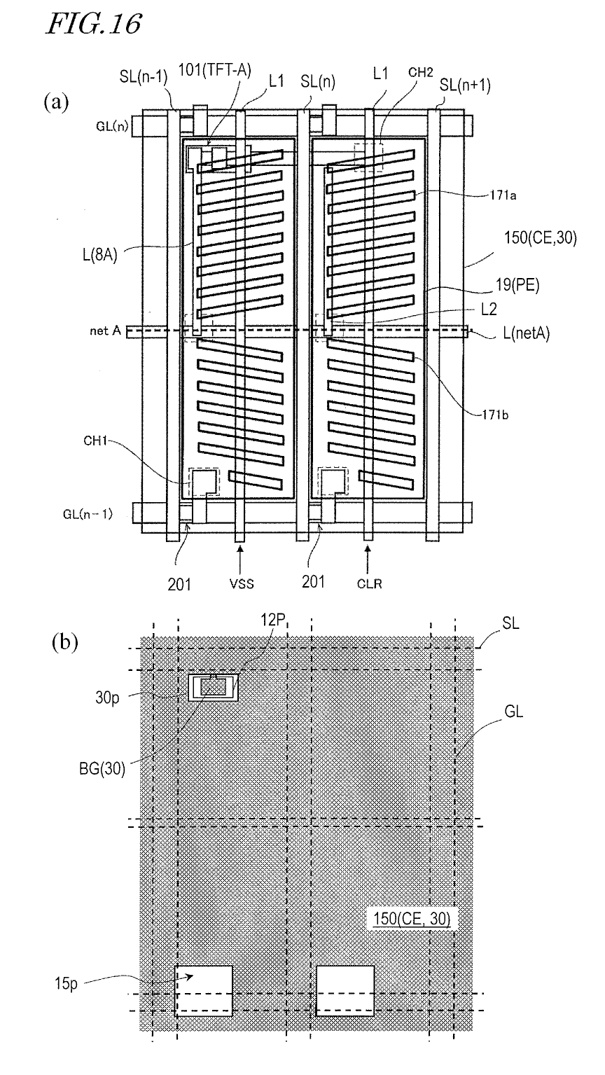

FIG. 16(a) is a plan view illustrating a pixel region in a part of the semiconductor device 1008. Each pixel region includes the first TFT 101, the second TFT 201, which is a pixel TFT, the pixel electrode PE (here, the upper transparent electrode 19) and the common electrode CE (here, the lower transparent electrode 15), and additionally includes a part of the gate driver 50. The first TFT 101 is TFT-A in the circuit shown in FIG. 15, for example. A plurality of slit portions 171 (171a, 171b) are provided in the pixel electrode PE.

The shield layer 30 is formed from the same transparent conductive film as the common electrode CE, for example. In this example, the common electrode CE and the shield layer 30 are formed integral together. Herein, a layer 150 including the common electrode CE and the shield layer 30 is referred to as a “transparent conductive layer”.

FIG. 16(b) is a plan view illustrating the transparent conductive layer 150. As shown in the figure, the transparent conductive layer 150 covers the entire display region. The transparent conductive layer 150 has openings 15p over second TFTs 201.

Portions of the transparent conductive layer 150 that cover elements and lines of the gate drivers 50 function as the shield layer 30, and it is thereby possible to prevent the display non-uniformity. On a cross section that extends across the gate driver 50, the shield layer 30 may be arranged between the gate driver 50 and the pixel electrode PE.

The organic insulating layer 12 has openings 12P over some or all of the circuit TFTs (here, TFT-A). A part of the shield layer 30 is arranged in the opening 12P and functions as the back gate electrode BG of TFT-A.

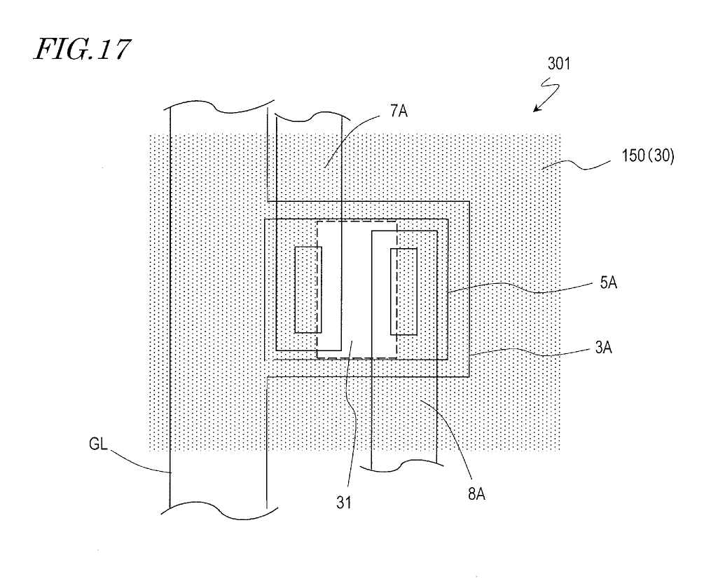

The gate driver 50 may further include another circuit TFT (third TFT) forming the circuit. The third TFT may not have the backgate structure, for example. For example, as illustrated in FIG. 17, the transparent conductive layer 150 may have the opening 31 over at least the channel region of the third TFT 301.

Note that the cross-sectional structure of the first TFT 101 and the second TFT 201 of the present embodiment may be similar to the various embodiments described above. Note however that when the shield layer 30 is formed in the same layer as the pixel electrode PE, the area of the pixel electrode PE will be small because the pixel electrode PE is not arranged over the gate driver 50. When the common electrode CE is used as the upper transparent electrode 19, and the common electrode CE and the shield layer 30 are formed integral together, if the pixel electrode PE is arranged between the gate driver 50 and the shield layer 30, the circuit may possibly malfunction due to the pixel electrode PE. Thus, the pixel electrode PE cannot be arranged over the gate driver 50, and the area of the pixel electrode PE will be small. Therefore, it is preferred that the lower transparent electrode 15 is the common electrode CE and that the common electrode CE and the shield layer 30 are formed integral together. Thus, it is possible to increase the proportion of the region that contributes to display with respect to the entire pixel region. Note however that when a part of the shield layer 30 (a part of the shield portion 30s) over the gate driver 50 is removed in order to prevent the characteristic fluctuation, the area of the pixel electrode PE will be small as in a case in which the pixel electrode PE and the shield layer 30 are formed in the same layer.

The first TFT 101 and the second TFT 201 may be either of the etch stop-type or of the channel-etch type. Although it is preferred that the organic insulating layer 12 is provided between the transparent conductive layer 150 and the first TFT 101 and the second TFT 201, the organic insulating layer 12 may be absent. In such a case, it may have the cross-sectional structure shown in FIG. 12.

Although the first to third embodiments described above each illustrate a gate driver as the circuit including the first TFT 101, it may be a circuit other than a gate driver.

An active matrix substrate according to an embodiment of the present invention can desirably be used in a liquid crystal display device for producing display in a transverse electric field mode such as an FFS mode. Although the first to third embodiments described above are each directed to an active matrix substrate of a liquid crystal display device that produces display in an FFS mode, the present invention is widely applicable to a semiconductor device having two transparent electrodes formed with a dielectric layer therebetween.

### INDUSTRIAL APPLICABILITY

The embodiment of the present invention is widely applicable to oxide semiconductor TFTs and various semiconductor devices including oxide semiconductor TFTs. For example, it is applicable to circuit boards such as active matrix substrates, display devices such as liquid crystal display devices, organic electroluminescence (EL) display devices and inorganic electroluminescent display devices, image pickup devices such as image sensor devices, and various electronic devices such as image input devices, fingerprint reader devices and semiconductor memory devices.

### REFERENCE SIGNS LIST

1 Substrate
3A, 3B Gate electrode
4 Gate insulating layer
5A, 5B Oxide semiconductor layer
7A, 7B Source electrode
8A, 8B Drain electrode
9 Protection layer
11 Inorganic insulating layer
12 Organic insulating layer
12P Opening
13 Interlayer insulating layer
15 Lower transparent electrode
15p Opening
17 Dielectric layer
19 Upper transparent electrode
30 Shield layer
30c Connecting portion of shield layer
30p Opening of shield layer
30s Shield portion of shield layer
50 Gate driver
150 Transparent conductive layer
101 First TFT (circuit TFT having backgate structure)
201 Second TFT (pixel TFT)
301 Third TFT (circuit TFT not having backgate structure)
800 Display region
900 Non-display region
1001, 1002, 1003, 1004, 1005, 1006, 1007, 1008 Semiconductor device
BG Backgate electrode
CE Common electrode
PE Pixel electrode
GL Gate line
SL Source line

1: A semiconductor device having a display region including a plurality of pixels, the semiconductor device comprising:
a substrate;
a plurality of oxide semiconductor TFTs including a first TFT and a second TFT formed on the substrate, wherein the second TFT is arranged in each of the plurality of pixels;
at least one circuit including the first TFT;
an inorganic insulating layer covering the first TFT and the second TFT;
a lower transparent electrode provided above the inorganic insulating layer in the display region;
an upper transparent electrode arranged on the lower transparent electrode with a dielectric layer therebetween; and
a shield layer formed from the same transparent conductive film as the lower transparent electrode or the upper transparent electrode, the shield layer covering the at least one circuit, wherein:
each of the plurality of oxide semiconductor TFTs includes a first gate electrode, a gate insulating layer covering the first gate electrode, an oxide semiconductor layer arranged so as to oppose the first gate electrode with the gate insulating layer therebetween, and a source electrode and a drain electrode connected to the oxide semiconductor layer;
one of the lower transparent electrode and the upper transparent electrode is a pixel electrode, the other one of the lower transparent electrode and the upper transparent electrode is a common electrode, and the drain electrode of the second TFT is electrically connected to the pixel electrode;
the shield layer is electrically connected to the common electrode;
the shield layer includes a second gate electrode arranged so as to overlap at least a part of a channel region of the oxide semiconductor layer of the first TFT, as seen from a direction normal to the substrate; and
(a) the second gate electrode is arranged on the inorganic insulating layer so as to be in contact with an upper surface of the inorganic insulating layer, or (b) over the channel region of the first TFT, the dielectric layer is in contact with the upper surface of the inorganic insulating layer, and the second gate electrode is arranged on the dielectric layer so as to be in contact with an upper surface of the dielectric layer.

2: The semiconductor device of claim 1, wherein the second gate electrode is not provided in the second TFT.

3: The semiconductor device of claim 1, wherein:
the plurality of oxide semiconductor TFTs further include a third TFT; and
the at least one circuit includes the third TFT, and the second gate electrode is not provided in the third TFT.

4: The semiconductor device of claim 1, further comprising an organic insulating layer arranged between the inorganic insulating layer and the lower transparent electrode and the shield layer, wherein:
the organic insulating layer has an opening through which a part of the inorganic insulating layer is exposed, and the opening is arranged so as to overlap at least the channel region of the oxide semiconductor layer of the first TFT, as seen from a direction normal to the substrate; and
the shield layer includes a shield portion that is located on the organic insulating layer, a connecting portion that is located on a side wall of the opening, and the second gate electrode that is located on a portion of the inorganic insulating layer exposed through the opening.

5: The semiconductor device of claim 4, wherein the shield layer has an opening between the shield portion and the second gate electrode.

6: The semiconductor device of claim 4, wherein:
the plurality of oxide semiconductor TFTs further include a third TFT;
the at least one circuit includes the third TFT; and
the oxide semiconductor layer of the third TFT is covered by the organic insulating layer, and the shield layer has an opening over the third TFT.

7: The semiconductor device of claim 4, wherein a thickness of the organic insulating layer is 1 μm or more and 3 μm or less.

8: The semiconductor device of claim 1, wherein:
the plurality of oxide semiconductor TFTs further include a third TFT;
the at least one circuit includes the third TFT;
an organic insulating layer is not provided between the inorganic insulating layer and the shield layer; and
the shield layer has an opening over the third TFT.

9: The semiconductor device of claim 1, wherein the at least one circuit is provided in a non-display region around the display region.

10: The semiconductor device of claim 1, wherein:
the at least one circuit is provided in the display region; and
the first TFT is located in one of the plurality of pixels, and the shield layer and the common electrode are formed integral together.

11: The semiconductor device of claim 1, wherein a thickness of the inorganic insulating layer is 100 nm or more and 500 nm or less.

12: The semiconductor device of claim 1, wherein the at least one circuit includes a gate driver.

13: The semiconductor device of claim 1, wherein the plurality of oxide semiconductor TFTs are etch stop-type TFTs.

14: The semiconductor device of claim 1, wherein the plurality of oxide semiconductor TFTs are channel-etch type TFTs.

15: The semiconductor device of claim 1, wherein the oxide semiconductor layer includes an In—Ga—Zn—O-based semiconductor.

16: The semiconductor device of claim 15, wherein the In—Ga—Zn—O-based semiconductor includes a crystalline portion.

17: The semiconductor device of claim 1, wherein the oxide semiconductor layer has a layered structure.

18: A method for manufacturing a semiconductor device having a display region in which a plurality of pixels are arranged, the method comprising the steps of:
(A) forming a plurality of oxide semiconductor TFTs including a first TFT and a second TFT, and at least one circuit including the first TFT, on a substrate, wherein the second TFT is arranged in each of the plurality of pixels;
(B) forming an inorganic insulating layer so as to cover the first TFT and the second TFT;
(C) forming a first transparent conductive film above the inorganic insulating layer and patterning the first transparent conductive film so as to form a lower transparent electrode;
(D) forming a dielectric layer on the lower transparent electrode;
(E) forming a second transparent conductive film on the dielectric layer and patterning the second transparent conductive film so as to form an upper transparent electrode; and
(F) patterning the first transparent conductive film or the second transparent conductive film so as to form a shield layer covering the at least one circuit, wherein:
each of the plurality of oxide semiconductor TFTs includes a first gate electrode, a gate insulating layer covering the first gate electrode, an oxide semiconductor layer arranged so as to oppose the first gate electrode with the gate insulating layer therebetween, and a source electrode and a drain electrode connected to the oxide semiconductor layer;
one of the lower transparent electrode and the upper transparent electrode is a pixel electrode, and the other one of the lower transparent electrode and the upper transparent electrode is a common electrode;
the shield layer is electrically connected to the common electrode;
the shield layer includes a second gate electrode arranged so as to overlap at least a part of a channel region of the oxide semiconductor layer of the first TFT, as seen from a direction normal to the substrate; and
(a) the second gate electrode is arranged on the inorganic insulating layer so as to be in contact with an upper surface of the inorganic insulating layer, or (b) over the channel region of the first TFT, the dielectric layer is in contact with the upper surface of the inorganic insulating layer, and the second gate electrode is arranged on the dielectric layer so as to be in contact with an upper surface of the dielectric layer.

19: The method for manufacturing a semiconductor device of claim 18, further comprising, between the step (B) and the step (C), the step of forming an organic insulating layer on the inorganic insulating layer, and forming an opening in the organic insulating layer through which a part of the inorganic insulating layer is exposed, wherein:
the opening is arranged so as to overlap at least the channel region of the oxide semiconductor layer of the first TFT, as seen from a direction normal to the substrate; and
the shield layer includes a shield portion that is located on the organic insulating layer, a connecting portion that is located on a side wall of the opening, and the second gate electrode that is located on a portion of the inorganic insulating layer exposed through the opening.
